(19) United States
(12) Patent Application Publication
(10) Pub. No.: US 2008/0284011 A1
(43) Pub. Date: Nov. 20, 2008

(54) BUMP STRUCTURE

(75) Inventors: Shyh-Ming Chang, Hsinchu City (TW); Ngai Tsang, Tainan City (TW); Kuo-Shu Kao, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignees: TAIWAN TFT LCD ASSOCIATION, Hsinchu (TW); CHUNGHWA PICTURE TUBES, LTD., Taipei (TW); AU OPTRONICS CORPORATION, Hsinchu (TW); HANNSTAR DISPLAY CORPORATION, Tao-Yuan Hsien (TW); CHI MEI OPTOELECTRONICS CORPORATION, Tainan County (TW); INDUSTRIAL TECHNOLOGY RESEARCH INSTITUTE, Hsinchu (TW); TPO DISPLAYS CORP., Miao-Li County (TW)

(21) Appl. No.: 11/834,696

(22) Filed: Aug. 7, 2007

(30) Foreign Application Priority Data
May 18, 2007 (TW) 96117782

(51) Int. Cl. H01L 23/48

(52) U.S. Cl. 257/737; 257/E23.01

(57) ABSTRACT

A bump structure including at least one contact pad, at least one first polymer bump, at least one second polymer bump, and a conductive layer is provided. The contact pad is disposed on a substrate, and the first polymer bump is also disposed on the substrate. The second polymer bump is disposed on the substrate and is connected to the first polymer bump. The conductive layer covers the first polymer bump and electrically connects the contact pad.

### CROSS-REFERENCE TO RELATED APPLICATION

This application claims the priority benefit of Taiwan application serial no. 96117782, filed May 18, 2007. All disclosure of the Taiwan application is incorporated herein by reference.

### BACKGROUND OF THE INVENTION

1. Field of the Invention

The present invention relates to a compliant bump. More particularly, the present invention relates to a compliant bump possessing enhanced structural strength by increasing a bottom area of the bump.

2. Description of Related Art

With rapid advancement of the display industry, flat-panel display technology has been evolved toward desired quality. Image resolution of displays is continuously improved, and modules of the displays are gradually equipped with positive attributes including lightness, thinness compactness, shortness and compactness. In line with said advancement, the package technology evolving from a chip-on-board (COB) bonding technology to a tape-automated-bonding (TAB) technology is now advanced to a fine-pitch chip-on-glass (COG) bonding technology.

The most common COG bonding process usually adopts an anisotropic conductive film (ACF) as a medium by which a chip and a glass substrate are electrically connected to each other. Through contacting gold bumps of the chip and metal pad plates of the glass substrate, conductive participles of the ACF are contributed to electrical conductivity. However, when a pitch between two adjacent leads is less than 20 micrometers, current leakage or short circuit is apt to occur between the two adjacent leads. Therefore, employing a non-conductive film as the medium through which the chip and the glass substrate are electrically connected to each other has been proposed, so as to resolve the issue of current leakage or short circuit arisen from the conductive particles embedded in the ACF.

As the pitch between the two adjacent leads is reduced, an area of the compliant bump has to be correspondingly decreased, which lowers an adhesive force between the compliant bump and the substrate. Thereby, the compliant bump may crack or peel off, reducing yield of products.

U.S. Pat. No. 5,877,556 discloses a bump structure in which a strip-shaped polymer bump is formed on a substrate. Thereafter, a plurality of strip-shaped conductive layers is formed on the polymer bump. Each of the conductive layers electrically connects a corresponding contact pad. However, since a top area of the whole strip-shaped is excessively large, a comparatively significant force may be applied when a flip chip bonding is performed. Moreover, after an adhesive is solidified, the relatively large bounce force is likely to open the bump between the chip and the glass substrate. Further, during the flip chip bonding, the adhesive confined within four polymer bumps results in great internal pressure, thus requiring a sufficient bonding force for conducting contacts and leading to the unlikelihood of removing the adhesive.

### SUMMARY OF THE INVENTION

The present invention is directed to a bump structure in which an auxiliary polymer bump is disposed in peripheral areas of a polymer bump, so as to increase a bottom area of a compliant bump, and an adhesive force between the compliant bump and the substrate is further increased. As such, as the area of compliant bump is decreased, the compliant bump can be prevented from cracking or peeling off, improving yield of the compliant bump.

The present invention is further directed to a bump structure adapted to a chip having a passivation layer. In the bump structure, a polymer protection layer is formed on a substrate when a corresponding polymer bump is simultaneously constructed on each contact pad. Thereby, the polymer protection layer is not only capable of protecting devices, but also able to enhance structural strength of the polymer bump, thus avoiding the polymer bump from cracking or peeling off from the substrate.

The present invention provides a bump structure including at least one contact pad, at least one first polymer bump, at least one second polymer bump, and a conductive layer. The contact pad is disposed on a substrate, and the first polymer bump is also disposed on the substrate. The second polymer bump is disposed on the substrate and is connected to the first polymer bump. The conductive layer covers the first polymer bump and electrically connects the contact pad.

According to an embodiment of the present invention, the first polymer bump is disposed outside the contact pad, partially disposed on the contact pad, or completely disposed on the contact pad.

According to an embodiment of the present invention, the second polymer bump is connected to any side of the first polymer bump, connected to more than two sides thereof, or connected to peripheral areas thereof.

According to an embodiment of the present invention, the second polymer bump is connected to two first polymer bumps or more.

According to an embodiment of the present invention, a height of the second polymer bump is less than or equal to that of the first polymer bump.

According to an embodiment of the present invention, a junction between the second polymer bump and the first polymer bump has a trench or several holes.

According to an embodiment of the present invention, the conductive layer wholly or partially covers the first polymer bump.

According to an embodiment of the present invention, the conductive layer wholly covers the second polymer bump, partially covers the same, or uncovers the same.

According to an embodiment of the present invention, the bump structure further includes a passivation layer disposed on the substrate for exposing the contact pad.

The present invention further provides a bump structure including at least one contact pad, at least one first polymer bump, a polymer protection layer and a conductive layer. The contact pad is disposed on a surface of a substrate, and the first polymer bump is also disposed on the surface of the substrate. The polymer protection layer covers the surface of the substrate and connects the first polymer bump. Here, the first polymer bump and the polymer protection layer are formed by the same film layer. The conductive layer covers the first polymer bump and electrically connects the contact pad.

According to an embodiment of the present invention, the first polymer bump is disposed outside the contact pad, partially disposed on the contact pad, or completely disposed on the contact pad.

According to an embodiment of the present invention, the conductive layer covers the first polymer bump and extends above a portion of the polymer protection layer.

According to an embodiment of the present invention, the first polymer bump is disposed on the polymer protection layer, the conductive layer covers a portion of the polymer protection layer and the first polymer bump, and the contact pad electrically connects the conductive layer.

According to an embodiment of the present invention, a junction between the polymer protection layer and the first polymer bump has a trench or several holes.

According to an embodiment of the present invention, the bump structure further includes a second polymer bump disposed on the polymer protection layer and connected to the first polymer bump.

According to an embodiment of the present invention, the second polymer bump is connected to any side of the first polymer bump, connected to more than two sides thereof, or connected to peripheral areas thereof.

According to an embodiment of the present invention, the second polymer bump is connected to two adjacent first polymer bumps or more.

According to an embodiment of the present invention, a height of the second polymer bump is less than or equal to that of the first polymer bump.

According to an embodiment of the present invention, a junction between the second polymer bump and the first polymer bump has a trench or several holes.

According to an embodiment of the present invention, the bump structure further includes a passivation layer disposed on the substrate for exposing the contact pad.

In the bump structure of the present invention, the second polymer bump connecting peripheral areas of the first polymer bump is used as the auxiliary bump for increasing the bottom area of the compliant bump and further for improving the adhesive force between the compliant bump and the substrate. As such, when the area of compliant bump is decreased, the compliant bump can be prevented from cracking or peeling off, thus improving yield of the compliant bump.

In order to make the aforementioned and other objects, features and advantages of the present invention more comprehensible, several embodiments accompanied with figures are described in detail below.

### BRIEF DESCRIPTION OF THE DRAWINGS

FIG. 1 is a schematic top view of a bump structure according to a first embodiment of the present invention.

FIGS. 2A˜2F are schematic cross-sectional views taken along lines I-I,II-II,III-III,IV-IV,V-V and VI-VI of FIG. 1.

FIG. 2G is a schematic cross-sectional view illustrating a trench formed between a first polymer bump and a second polymer bump of FIG. 2A.

FIG. 2H is a schematic cross-sectional view illustrating a lead angle formed between a first polymer bump and a second polymer bump of FIG. 2A.

FIG. 3 is a schematic top view of a bump structure according to a second embodiment of the present invention.

FIGS. 4A˜4F are schematic cross-sectional views taken along lines I-I,II-II,III-III,IV-IV,V-V and VI-VI of FIG. 3.

FIG. 5 is a schematic top view of a bump structure according to a third embodiment of the present invention.

FIGS. 6A˜6D are schematic cross-sectional views taken along lines I-I,II-II,III-III and IV-IV of FIG. 5.

FIG. 7 is a schematic top view of a bump structure according to a fourth embodiment of the present invention.

FIGS. 8A˜8D are schematic cross-sectional views taken along lines I-I,II-II,III-III and IV-IV of FIG. 7.

FIG. 9 is a schematic top view of a bump structure according to a fifth embodiment of the present invention.

FIGS. 10A˜10D are schematic cross-sectional views taken along lines I-I,II-II,III-III and IV-IV of FIG. 9.

FIG. 11 is a schematic top view of a bump structure according to a sixth embodiment of the present invention.

FIGS. 12A˜12D are schematic cross-sectional views taken along lines I-I,II-II,III-III and IV-IV of FIG. 11.

### DESCRIPTION OF EMBODIMENTS

Generally, chips can be classified into the chips having passivation layers and the chips in the absence of the passivation layers. Descriptions of a bump structure applied to the chips having no passivation layers according to the present invention will be firstly provided hereinafter.

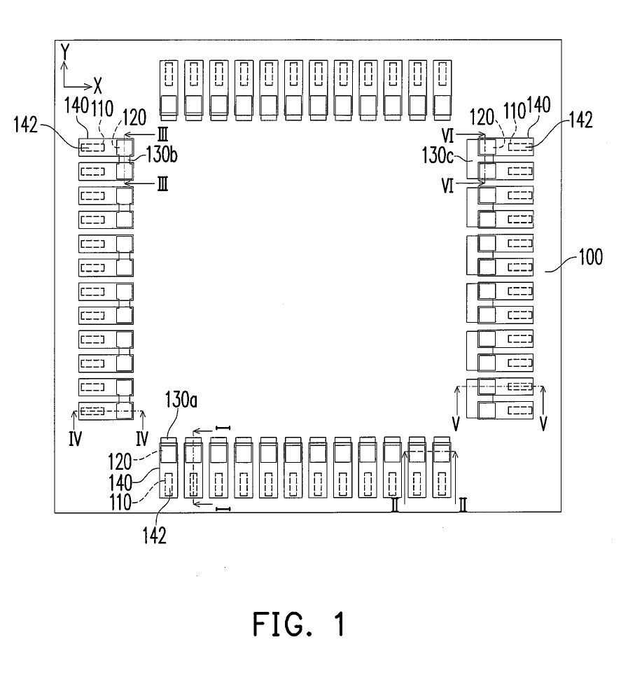

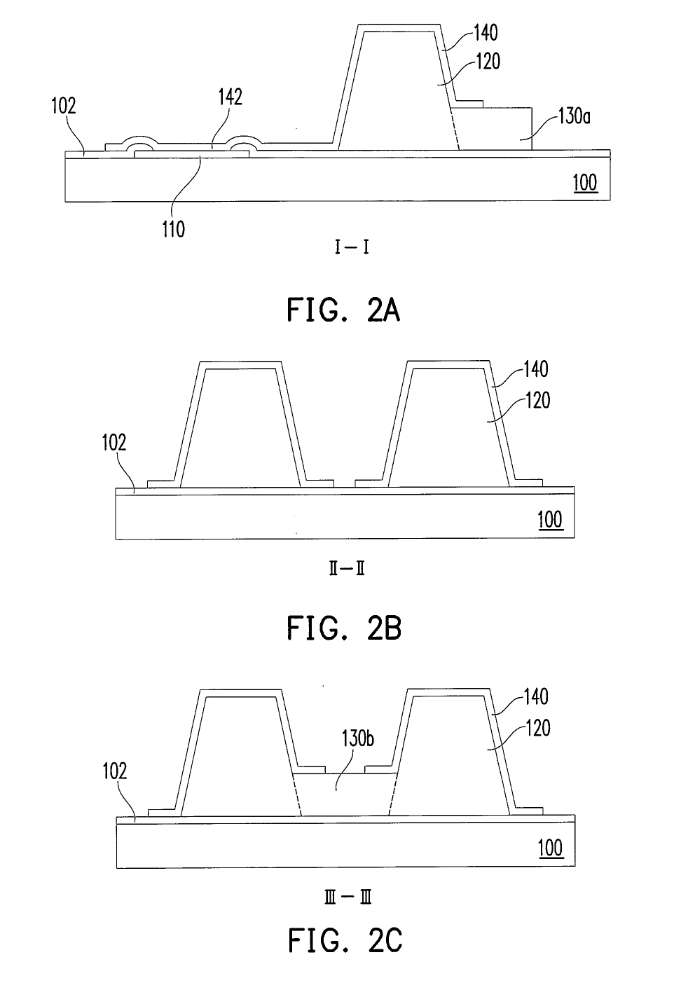

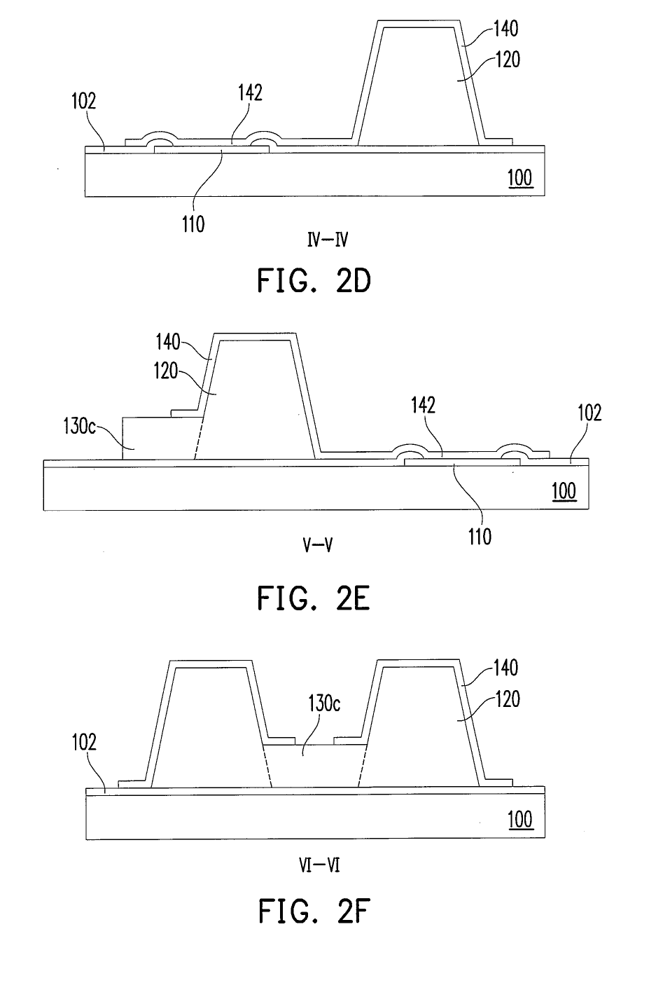

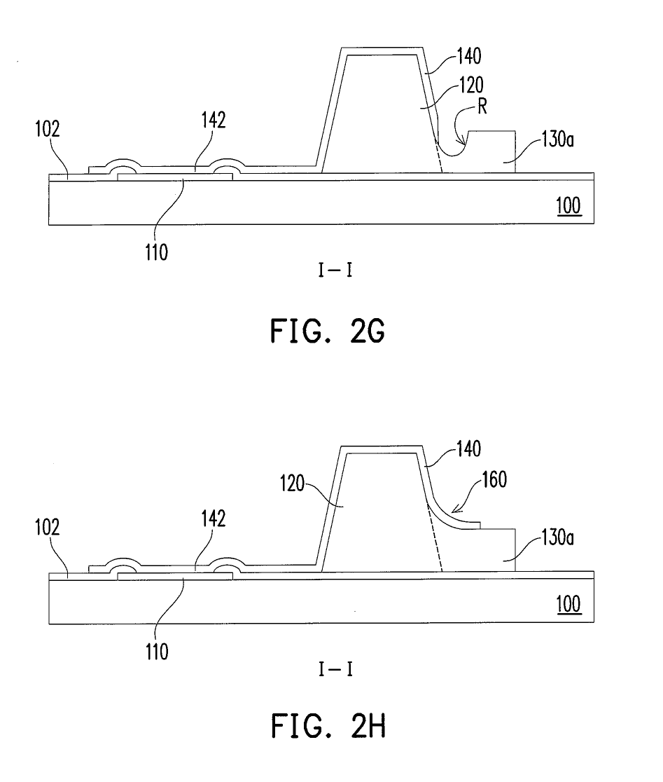

FIG. 1 is a schematic top view of a bump structure according to a first embodiment of the present invention. FIGS. 2A˜2F are schematic cross-sectional views taken along lines I-I,II-II,III-III,IV-IV,V-V and VI-VI of FIG. 1. FIG. 2G is a schematic cross-sectional view illustrating a trench formed between a first polymer bump and a second polymer bump of FIG. 2A. First of all, referring to FIGS. 1, 2A and 2B, the bump structure mainly includes a plurality of contact pads 110, a plurality of first polymer bumps 120, a plurality of second polymer bumps 130a and a plurality of conductive layers 140. In order to simplify the demonstration, one of the contact pads 110, the corresponding first polymer bump 120, the corresponding second polymer bump 130a, and the conductive layer 140 covering the contact pad 110 and the polymer bumps are taken to exemplify the present invention.

One of the contact pads 110 is disposed on a substrate 100. The contact pads 110 disposed at a left side and a right side of the substrate 100 are arranged in a Y direction, while the contact pads 110 disposed above and below the substrate 100 are arranged in an X direction. The substrate 100 may be, for example, a silicon substrate, a glass substrate, a print circuit board, a flexible circuit board, or a ceramic substrate. A plurality of electronic devices or a plurality of integrated circuits has been formed in the substrate 100, for example. A material of the contact pads 110 is metal, for example. Besides, in an embodiment of the present invention, a passivation layer 102 exposing the contact pad 110 may be alternatively formed on the substrate 100, so as to prevent the substrate 100 from being damaged. A material of the passivation layer 102 is, for example, silicon nitride or any other appropriate dielectric material.

According to the first embodiment, the first polymer bump 120 is disposed on the substrate 100 and positioned outside the contact pad 110. Moreover, a material of the first polymer bump 120 is, for example, polyimide (PI), epoxy resin or an acrylic material. The second polymer bump 130a is also disposed on the substrate 100 and is connected to peripheral areas of the first polymer bump 120. By connecting the second polymer bump 130a to one side of the first polymer bump 120 in the present invention, a bottom area of the first polymer bump 120 is increased. As such, an adhesive force between the polymer bumps and the substrate 100 can be enhanced, the polymer bumps can be avoided from cracking or peeling off, and yield of contacts is further improved. The first polymer bump 120 and the second polymer bump 130a connected to one side of the first polymer bump 120 may be formed by the same film layer.

It is known from FIGS. 1 and 2A that the second polymer bump 130a connects one side of the first polymer bump 120 and extends toward inside of the substrate 100 along the Y direction as shown in FIG. 1. Through the disposition of the second polymer bump 130a, the bottom area of the first polymer bump 120 is increased, so as to improve the adhesive force between the polymer bumps and the substrate 100 and to further prevent a compliant bump from cracking or peeling off. In addition, a height of the second polymer bump 130a may be less then that of the first polymer bump 120, which is conducive to removing an adhesive. However, the height of the second polymer bump 130a may also be equal to that of the first polymer bump 120.

Referring to FIGS. 1 and 2A again, the conductive layer 140 covers the first polymer bump 120 and electrically connects the contact pad 110. The conductive layer 140 extending to the peripheral areas of the first polymer bump 120 serve as a testing pad 142. Predicated on actual demands for designing the devices, the conductive layer 140 may extend to any point on the peripheral areas of the first polymer bump 120. In the present embodiment, the conductive layer 140 completely covers the first polymer bump 120 and partially covers the second polymer bump 130a. As such, the first polymer bump 120 and the conductive layer 140 disposed thereon together form the compliant bump. Moreover, a material of the conductive layer 140 is metal, for example. Besides, in the first embodiment, the testing pad 142 for performing an electrical examination is disposed above the contact pad 110.

With reference to FIGS. 2C and 2D, the bump structure depicted therein is substantially identical to that illustrated in FIGS. 2A and 2B. The difference therebetween mainly lies in that a second polymer bump 130b is connected between the two adjacent first polymer bumps 120 in the bump structure shown FIGS. 2C and 2D. As such, the connection between the second polymer bump 130b and the adjacent first polymer bumps 120 leads to an increase in structural strength of the compliant bump. In the present embodiment, the second polymer bump 130b is sandwiched between the two adjacent first polymer bumps 120. However, it is also likely to dispose the second polymer bump 130b between every two of the first polymer bumps 120 (i.e. forming a strip-shaped polymer bump as a whole), so as to further enhance structural strength of the compliant bump.

Next, referring to FIGS. 2E and 2F, the bump structure depicted therein is substantially identical to that illustrated in FIGS. 2A and 2B. The difference therebetween mainly lies in that a second polymer bump 130c is connected between the two adjacent first polymer bumps 120 and extends toward inside of the substrate 100 in the X direction as indicated in FIG. 1. The second polymer bump 130c connecting one side of the first polymer bump 120 not only extends toward inside of the substrate 100, but also connects the two adjacent first polymer bumps 120. Thereby, the bottom area of the first polymer bump 120 can be further increased, and the adhesive force between the polymer bumps and the substrate 100 is also improved.

Further, as shown in FIG. 2G, to prevent the conductive layer 140 formed on the first polymer bump 120 and the second polymer bump 130a as shown in FIG. 2A from cracking due to stress concentration, a trench R or several discontinuous holes (not shown) may be alternatively formed in a junction between the first polymer bump 120 and the second polymer bump 130a. Thereby, the conductive layer 140 can be avoided from cracking. According to one embodiment of the present invention, the conductive layer 140 may completely cover, partially cover or uncover the trench R (or the holes). Said design of the trench or the holes is suitable for any junction between the first polymer bump and the second polymer, such that the conductive layer covering the first polymer bump and the second polymer does not crack while the conductive function still remains.

Referring to FIG. 2H, except the above-mentioned trench R or several discontinuous holes, a lead angle 160 may be formed in a junction between the first polymer bump 120 and the second polymer bump 130a to prevent the conductive layer 140 formed on the first polymer bump 120 and the second polymer bump 130a from cracking.

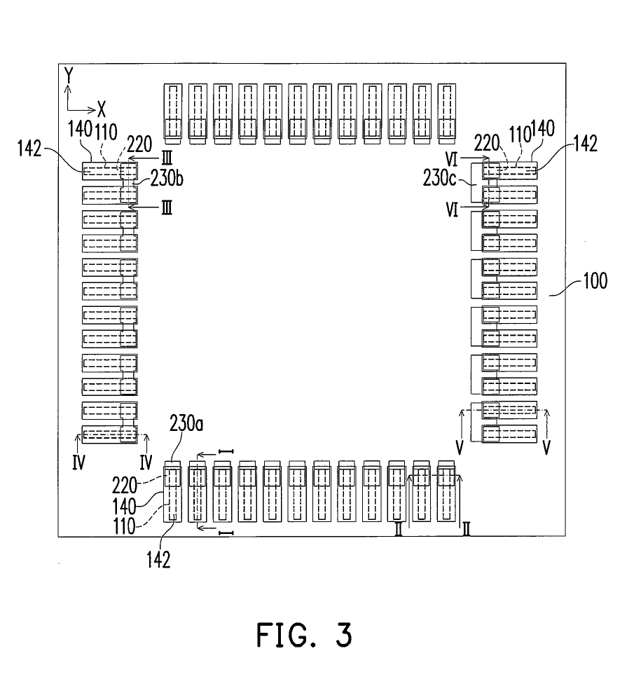

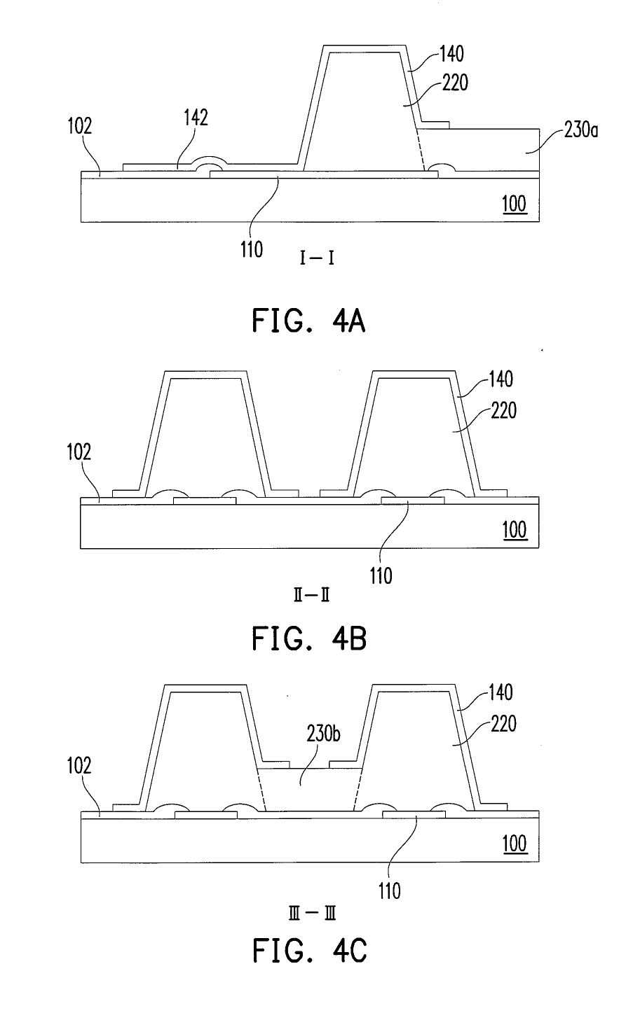

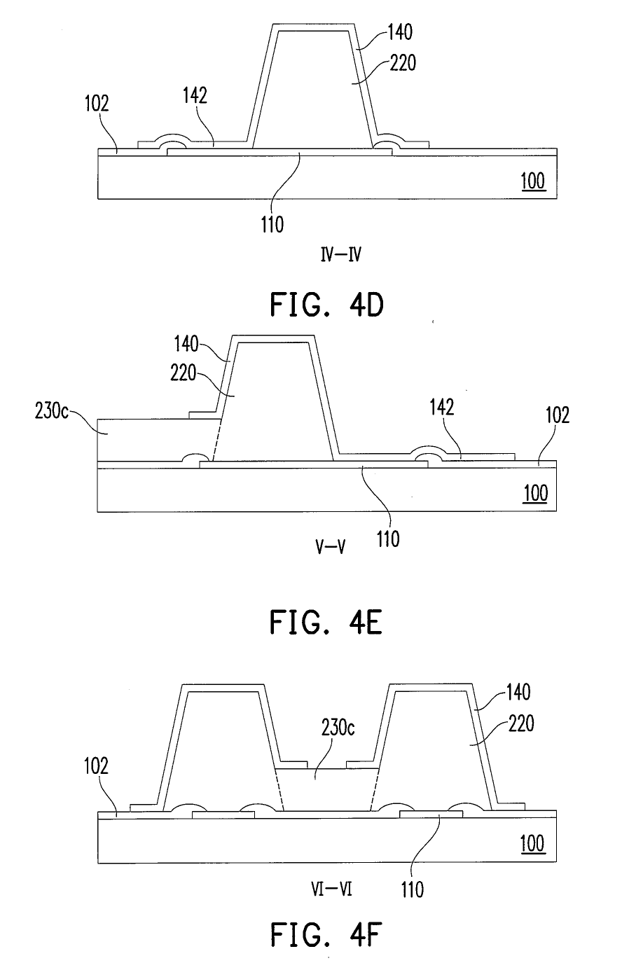

FIG. 3 is a schematic top view of a bump structure according to a second embodiment of the present invention. FIGS. 4A˜4F are schematic cross-sectional views taken along lines I-I,II-II,III-III,IV-IV,V-V and VI-VI of FIG. 3. First, referring to FIGS. 3, 4A and 4B, the bump structure depicted therein is substantially identical to that illustrated in FIGS. 1, 2A and 2B. Thus, no further description as to the bump structure is provided herein. The difference therebetween mainly lies in that a first polymer bump 220 of the second embodiment is completely disposed on the contact pad 110, and the testing pad 142 is disposed on the contact pad 110 outside the first polymer bump 220.

Likewise, in the bump structure indicated in FIGS. 4A and 4B, a second polymer bump 230a connects one side of the first polymer bump 220 and extends to inside of the substrate 100 along the Y direction as shown in FIG. 3, such that the bottom area of the first polymer bump 220 can be increased. By contrast, in the bump structure indicated in FIGS. 4C and 4D, a second polymer bump 230b is connected between the two adjacent first polymer bumps 220. Moreover, in the bump structure shown in FIGS. 4E and 4F, a second polymer bump 230c is connected between the two adjacent first polymer bumps 220 and extends to inside of the substrate 100 along a -X direction as illustrated in FIG. 3. Although the second polymer bumps 230a, 230b and 230c all connected to the first polymer bump 220 extend along different directions (X direction or Y direction), it is desired to increase the bottom area of the first polymer bump 220 through the disposition of the second polymer bumps. Thereby, the adhesive force between the polymer bumps and the substrate 100 can be enhanced, and yield of the compliant bump is raised.

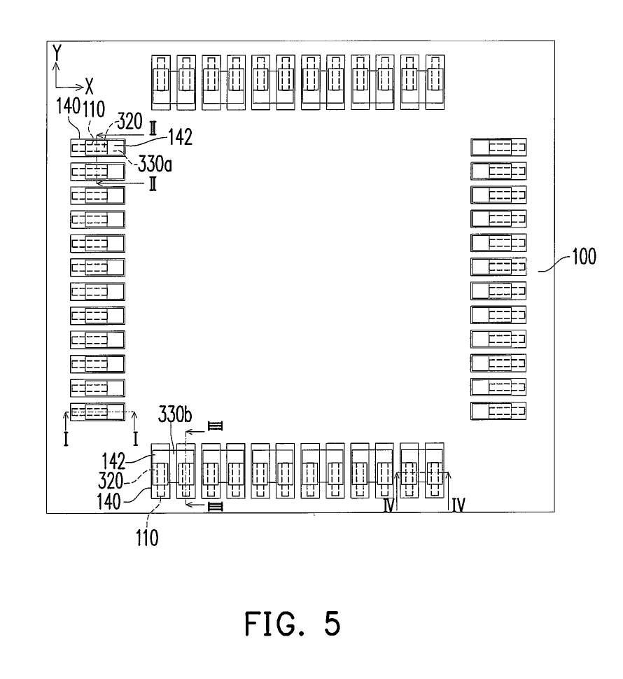

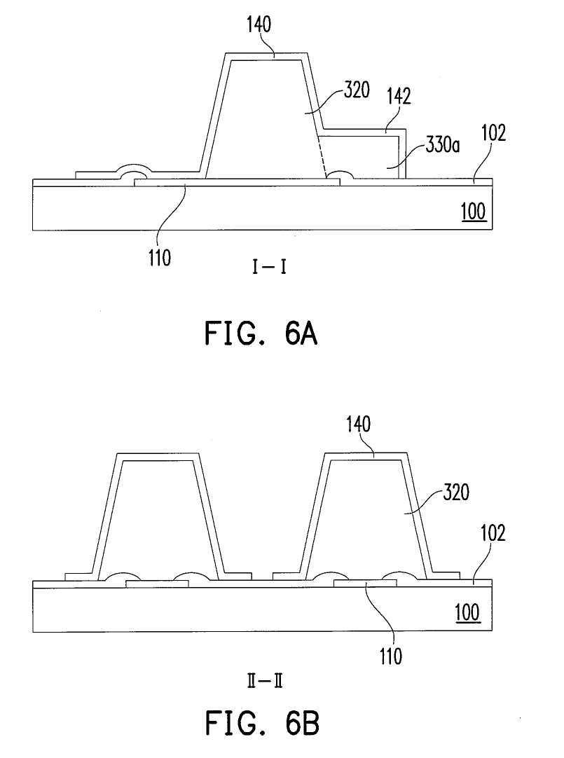

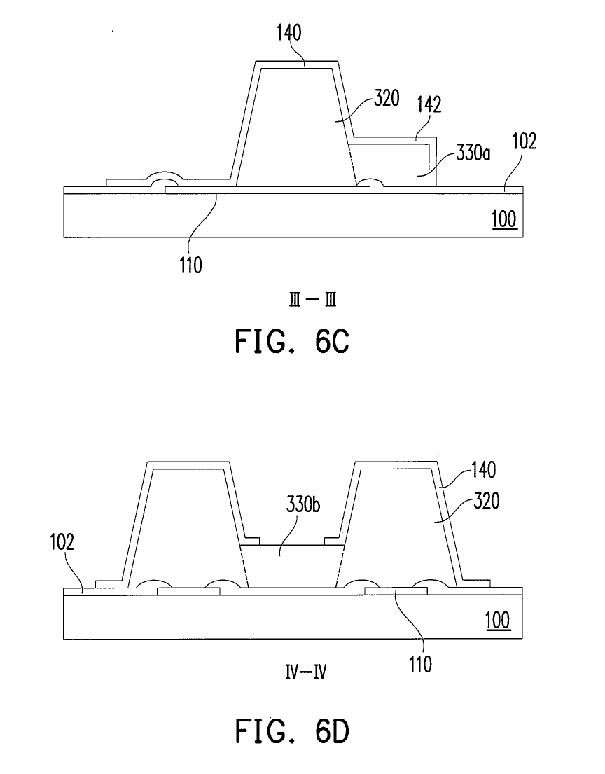

FIG. 5 is a schematic top view of a bump structure according to a third embodiment of the present invention. FIGS. 6A˜6D are schematic cross-sectional views taken along lines I-I,II-II,III-III and IV-IV of FIG. 5. First, referring to FIGS. 5, 6A and 6B, the bump structure depicted therein is substantially identical to that illustrated in FIGS. 3, 4C and 4D. Thus, no further description as to the bump structure is provided herein. The difference therebetween lies in that a first polymer bump 320 of the third embodiment is completely disposed on the contact pad 110, and the conductive layer 140 wholly covers the first polymer bump 320 and a second polymer bump 330a. Thereby, the conductive layer 140 disposed on the second polymer bump 330a may serve as the testing pad 142 for conducting an electrical examination. Moreover, in the bump structure shown in FIGS. 6C and 6D, a second polymer bump 330b connects the two adjacent first polymer bumps 320 and extends along the Y direction as illustrated in FIG. 5.

Thereafter, descriptions of the bump structure applied to the chips equipped with the passivation layers according to the present invention will be provided hereinafter.

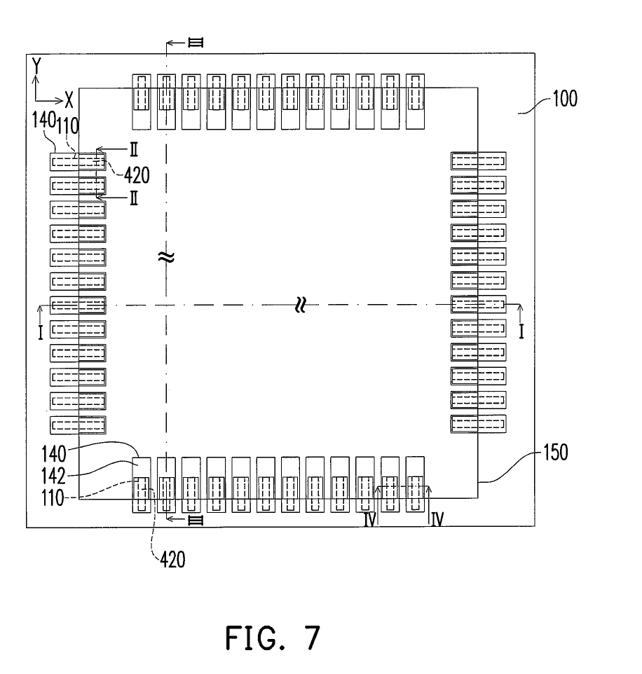

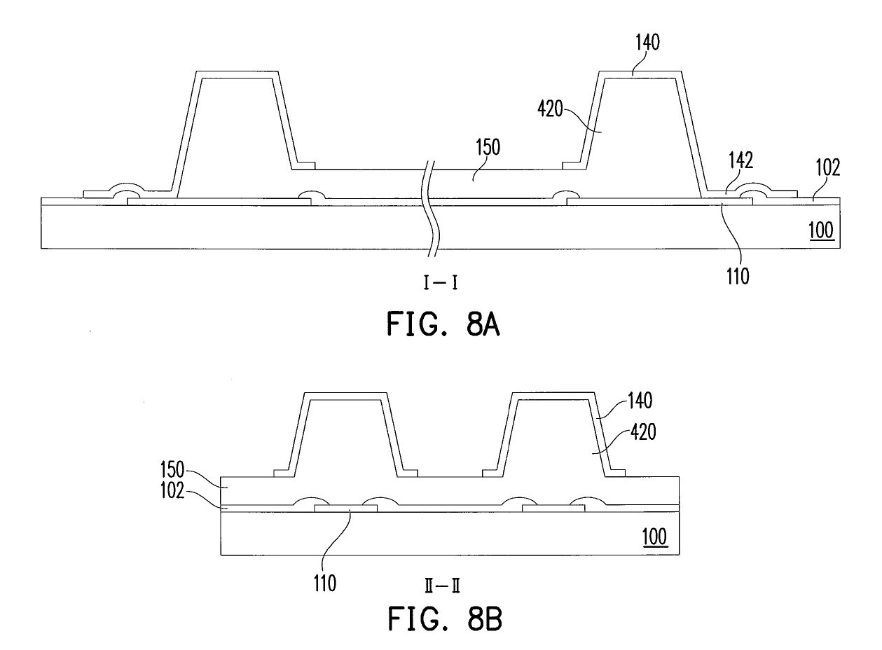

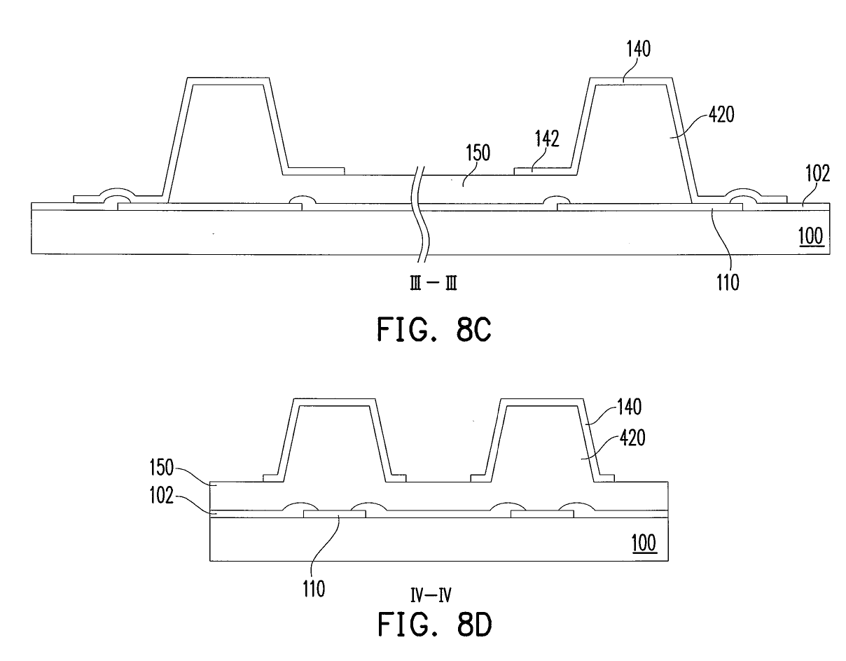

FIG. 7 is a schematic top view of a bump structure according to a fourth embodiment of the present invention. FIGS. 8A˜6D are schematic cross-sectional views taken along lines I-I,II-II,III-III and IV-IV of FIG. 7. First of all, referring to FIGS. 7, 8A and 8B, the bump structure mainly includes a plurality of contact pads 110, a plurality of first polymer bumps 420, a polymer protection layer 150 and a plurality of conductive layers 140.

The contact pads 110 are disposed on a substrate 100. The polymer protection layer 150 is disposed on a surface of the substrate 100, so as to protect devices formed on said surface from being damaged. In the present embodiment, as the polymer protection layer 150 is formed, the corresponding first polymer bump 420 is simultaneously constructed on each of the contact pads 110. The first polymer bumps 420 and the polymer protection layer 150 are made up of same materials, whereas a height of one of the first polymer bumps 420 is more than that of the polymer protection layer 150. Thereby, the polymer protection layer 150 is not only capable of protecting the devices, but also able to enhance structural strength of the first polymer bumps 420, avoiding the same from cracking or peeling off from the substrate 100.

Similarly, the conductive layers 140 cover the first polymer bumps 420 and electrically connect the contact pads 110. One of the conductive layers 140 extending to the peripheral areas of the first polymer bumps 420 may serve as the testing pad 142. In the present embodiment, the contact pads 110 have a greater length. As such, one of the first polymer bumps 420 is merely disposed on one part of the contact pad 110, and the conductive layer 140 disposed on the other part of the contact pad 110 serves as the testing pad 142 for conducting the electrical examination.

The bump structure depicted in FIGS. 8C and 8D is substantially identical to that illustrated in FIGS. 8A and 8B. However, the length of one of the contact pads 110 is rather short, and the first polymer bumps 420 are disposed on a part of the contact pads 110. Besides, the conductive layer 140 extends above a portion of the polymer protection layer 150, such that the conductive layer 140 can be used as the testing pad 142.

Furthermore, a trench or several discontinuous holes (not shown) may be alternatively formed in the junction between the first polymer bump 120 and the polymer protection layer 150 and/or in the junction between the first polymer bump 120 and the second polymer bump 130a. Thereby, the conductive layer 140 can be avoided from cracking due to stress concentration. In addition, the conductive layer 140 may wholly cover the trench (or the holes), partially cover the same, or uncover the same.

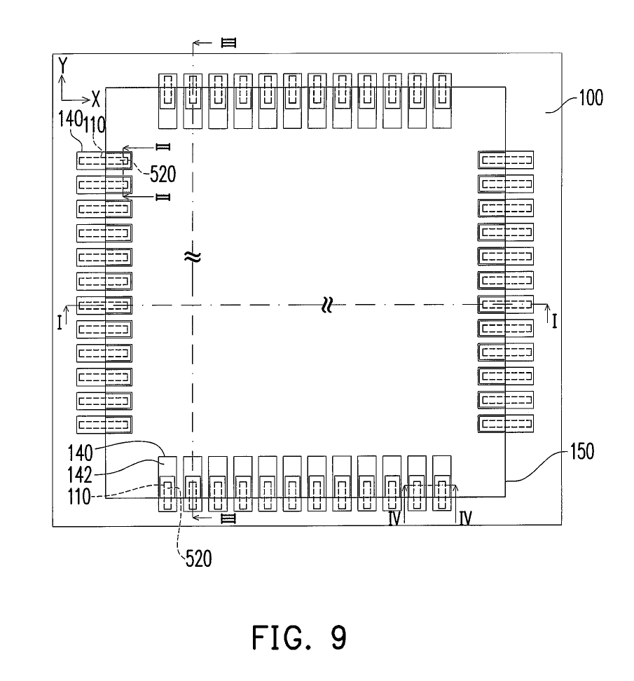

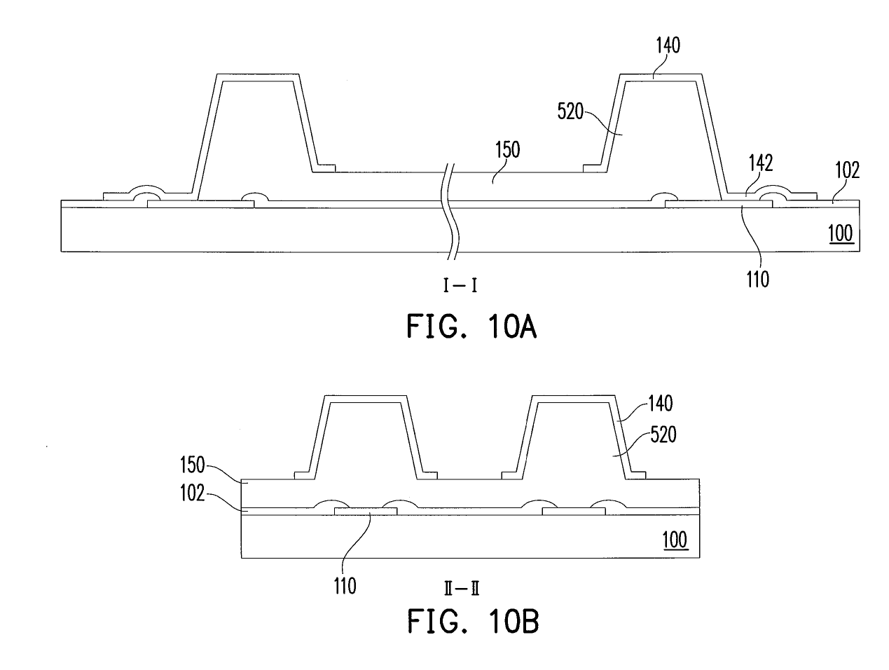

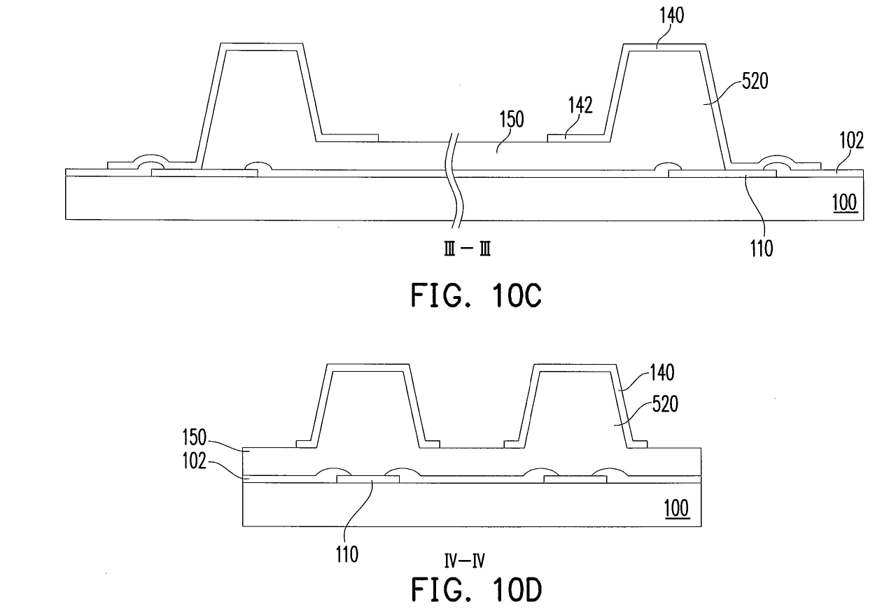

FIG. 9 is a schematic top view of a bump structure according to a fifth embodiment of the present invention. FIGS. 10A˜10D are schematic cross-sectional views taken along lines I-I,II-II,III-III and IV-IV of FIG. 9. First, referring to FIGS. 9, 10A and 10B, the bump structure depicted therein is substantially identical to that illustrated in FIGS. 7, 8A and 8B. Thus, no further description as to the bump structure is provided herein. The difference therebetween lies in that parts of first polymer bumps 520 are disposed on the contact pads 110 according to the fifth embodiment, whereas the other parts of the first polymer bumps 520 are disposed on the polymer protection layer 150. The conductive layer disposed on the contact pads 110 can serve as the testing pad 142.

The bump structure depicted in FIGS. 10C and 10D is substantially identical to that illustrated in FIGS. 10A and 10B. However, the length of one of the contact pads 110 is rather short, and thus the conductive layer 140 extending above a portion of the polymer protection layer 150 serves as the testing pad 142.

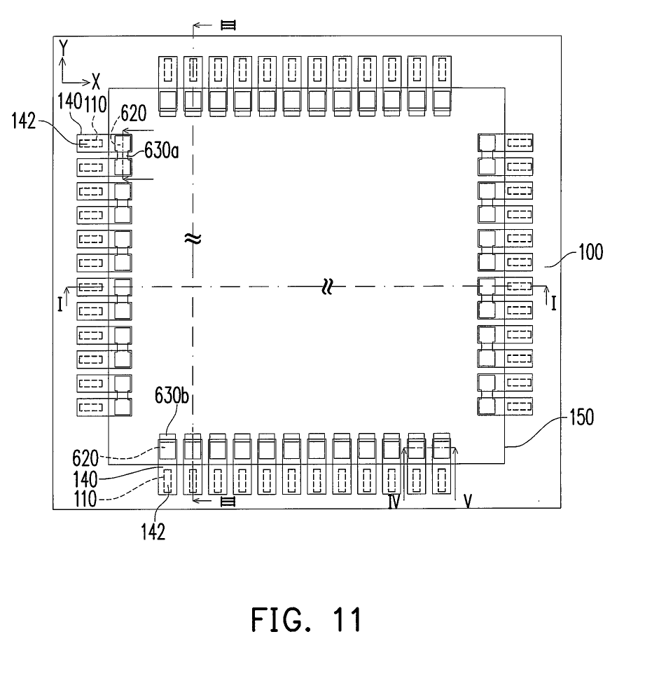

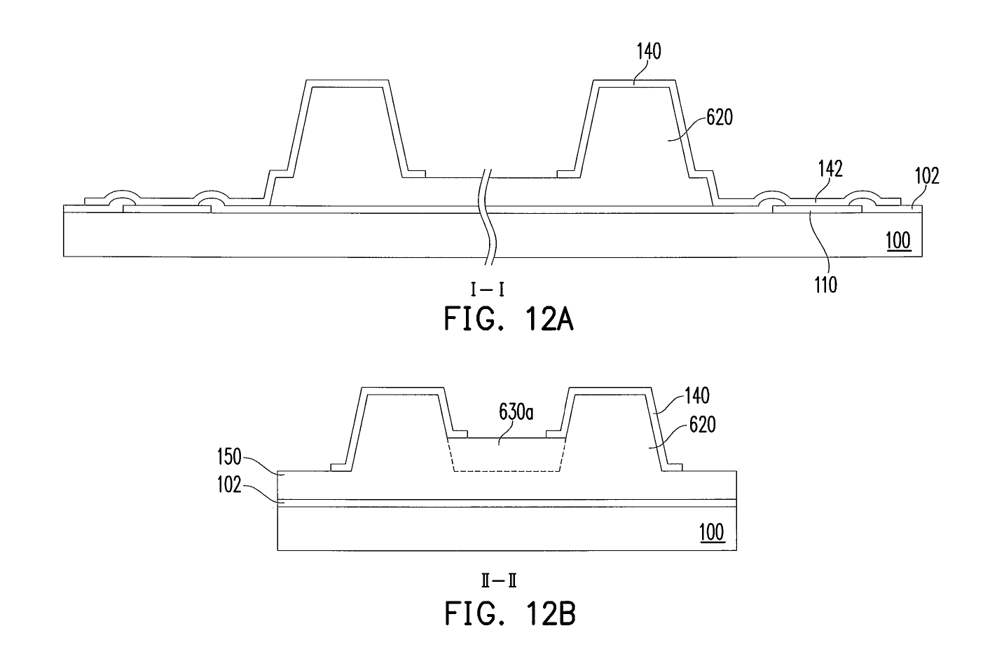

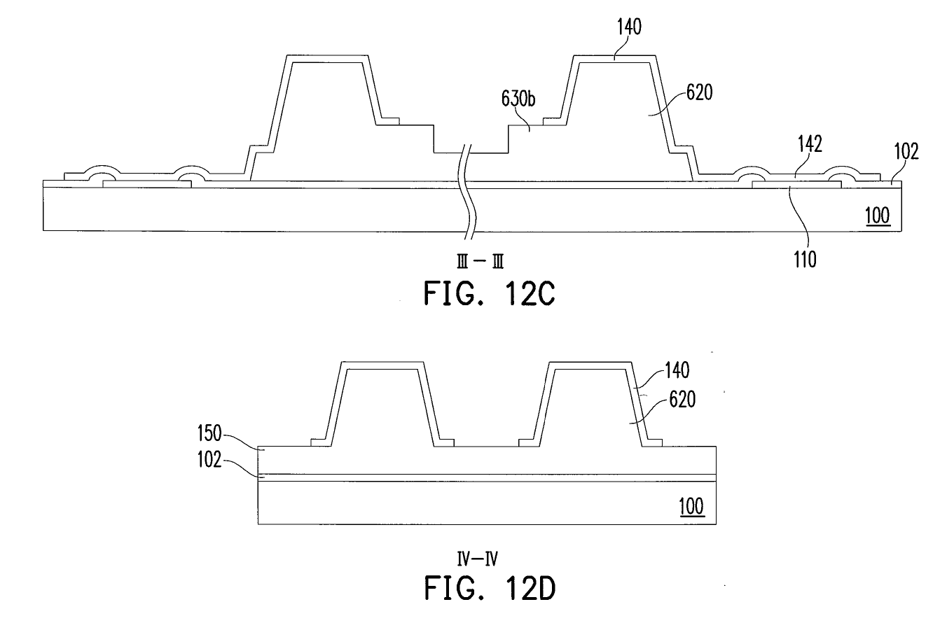

FIG. 11 is a schematic top view of a bump structure according to a sixth embodiment of the present invention. FIGS. 12A˜12D are schematic cross-sectional views taken along lines I-I,II-II,III-III and IV-IV of FIG. 11. First, referring to FIGS. 11, 12A and 12B, the bump structure depicted therein is substantially identical to that illustrated in FIGS. 9, 10A and 10B. Thus, no further description as to the bump structure is provided herein. The difference therebetween lies in that first polymer bumps 620 of the sixth embodiment are disposed outside the contact pads 110 and positioned on the polymer protection layer 150. The conductive layer 140 covers the first polymer bumps 620 and a portion of the polymer protection layer 150 and electrically connects the contact pads 110. Thereby, the conductive layer 140 disposed on the contact pads 110 can be used as the testing pad 142.

Moreover, in the bump structure illustrated in FIGS. 12A and 12B, a second polymer bump 630a connected between the two adjacent first polymer bumps 620 is further included, so as to enhance structural strength of the compliant bump. By contrast, in the bump structure indicated in FIGS. 12C and 12D, each of the first polymer bumps 620 is separated from one another. The second polymer bump 630b is connected to one side of one of the first polymer bumps 620 and extends along the Y direction as shown in FIG. 11. Thereby, the bump can be protected from damaging owing to a greater height thereof.

To sum up, in the bump structure of the present invention, the second polymer bump is disposed in the peripheral areas of the first polymer bump. The second polymer bump can be connected between two adjacent first polymer bumps or merely connected to one side of the first polymer bump. Through the disposition of the second polymer bump, the bottom area of the compliant bump is increased, and the adhesive force between the compliant bump and the substrate is further improved. Accordingly, as the area of compliant bump is decreased, the compliant bump can be prevented from cracking or peeling off, improving yield of the compliant bump.

The present invention is further directed to the bump structure adapted to the chip equipped with the passivation layer. In the bump structure, as the polymer protection layer is formed on the substrate, the corresponding polymer bump can be simultaneously constructed on each of the contact pads. Thereby, the polymer protection layer is not only capable of protecting devices, but also able to enhance structural strength of the polymer bump, avoiding the same from cracking or peeling off from the substrate.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A bump structure, comprising:
at least one contact pad disposed on a substrate;
at least one first polymer bump disposed on the substrate;
at least one second polymer bump disposed on the substrate and connected to the first polymer bump; and
a conductive layer covering the first polymer bump and electrically connecting the contact pad.

2. The bump structure as claimed in claim 1, wherein the first polymer bump is disposed outside the contact pad, partially disposed on the contact pad, or completely disposed on the contact pad.

3. The bump structure as claimed in claim 1, wherein the second polymer bump is connected to any side of the first polymer bump, connected to more than two sides thereof, or connected to peripheral areas thereof.

4. The bump structure as claimed in claim 1, wherein the second polymer bump is connected to two adjacent first polymer bumps or more.

5. The bump structure as claimed in claim 1, wherein a height of the second polymer bump is less than or equal to that of the first polymer bump.

6. The bump structure as claimed in claim 1, wherein a junction between the second polymer bump and the first polymer bump has a trench, a plurality of holes or a lead angle.

7. The bump structure as claimed in claim 1, wherein the conductive layer wholly or partially covers the first polymer bump.

8. The bump structure as claimed in claim 1, wherein the conductive layer wholly or partially covers the second polymer bump.

9. The bump structure as claimed in claim 1, further comprising a passivation layer disposed on the substrate for exposing the contact pad.

10. A bump structure, comprising:
at least one contact pad disposed on a surface of a substrate;
at least one first polymer bump disposed on the surface of the substrate;
a polymer protection layer covering the surface of the substrate and connecting the first polymer bump, wherein the first polymer bump and the polymer protection layer are formed by the same film layer; and
a conductive layer covering the first polymer bump and electrically connecting the contact pad.

11. The bump structure as claimed in claim 10, wherein the first polymer bump is disposed outside the contact pad, partially disposed on the contact pad, or completely disposed on the contact pad.

12. The bump structure as claimed in claim 10, wherein the conductive layer covers the first polymer bump and extends above a portion of the polymer protection layer.

13. The bump structure as claimed in claim 10, wherein the first polymer bump is disposed on the polymer protection layer, the conductive layer covers a portion of the polymer protection layer and the first polymer bump, and the contact pad electrically connects the conductive layer.

14. The bump structure as claimed in claim 10, wherein a junction between the polymer protection layer and the first polymer bump has a trench, a plurality of holes, or a lead angle.

15. The bump structure as claimed in claim 10, further comprising a second polymer bump disposed on the polymer protection layer and connected to the first polymer bump.

16. The bump structure as claimed in claim 15, wherein the second polymer bump is connected to any side of the first polymer bump, connected to more than two sides thereof, or connected to peripheral areas thereof.

17. The bump structure as claimed in claim 15, wherein the second polymer bump is connected to two adjacent first polymer bumps or more.

18. The bump structure as claimed in claim 15, wherein a height of the second polymer bump is less than or equal to that of the first polymer bump.

19. The bump structure as claimed in claim 15, wherein a junction between the second polymer bump and the first polymer bump has a trench or a plurality of holes.

20. The bump structure as claimed in claim 10, further comprising a passivation layer disposed on the substrate for exposing the contact pad.
